(19) United States
(12) Patent Application Publication
(10) Pub. No.: US 2016/0307833 A1
(43) Pub. Date: Oct. 20, 2016

(54) ELECTRONIC PACKAGING STRUCTURE AND METHOD FOR FABRICATING ELECTRONIC PACKAGE

(71) Applicant: Siliconware Precision Industries Co., Ltd., Taichung (TW)

(72) Inventors: Hsien-Wen Chen, Taichung (TW); Shih-Ching Chen, Taichung (TW); Hsiao-Chun Huang, Taichung (TW); Guang-Hwa Ma, Taichung (TW)

(21) Appl. No.: 14/981,588

(22) Filed: Dec. 28, 2015

(30) Foreign Application Priority Data
Apr. 14, 2015 (TW) 104111896

(51) Int. Cl. H01L 23/498; H01L 21/78; H01L 21/683; H01L 21/48; H01L 23/31; H01L 21/56

(52) U.S. Cl. CPC H01L 23/49838; H01L 23/49822; H01L 23/49827; H01L 23/3121; H01L 23/3142; H01L 21/563; H01L 21/6835; H01L 21/568; H01L 21/4853; H01L 21/78; H01L 2221/68381

(57) ABSTRACT

An electronic packaging structure is provided, including a circuit portion, an electronic element disposed on an upper side of the circuit portion and a glass carrier disposed on a lower side of the circuit portion. By replacing a conventional silicon wafer with the glass carrier, the present invention eliminates the need of an adhesive layer and allows quick removal of the glass carrier during a subsequent process, thus saving the fabrication time and increasing the product yield. The present invention further provides a method for fabricating an electronic package.

### BACKGROUND OF THE INVENTION

1. Field of the Invention

The present invention relates to fabrication methods of electronic packages, and more particularly, to a fabrication method of an electronic package for improving the product yield.

2. Description of Related Art

Along with the rapid development of electronic industries, electronic products are developed toward the trend of multi-function and high performance. Current chip packaging technologies have developed various types of flip-chip packaging modules such as chip scale packages (CSPs), direct chip attached (DCA) packages and multi-chip module (MCM) packages.

FIGS. 1A to 1F are schematic cross-sectional views showing a method for fabricating a semiconductor package 1 according to the prior art.

Referring to FIG. 1A, a semiconductor structure is provided. The semiconductor structure has a silicon wafer 10 having an adhesive layer 100 made of such as an oxide material, a circuit portion 11 formed on the adhesive layer 100 of the silicon wafer 10, a plurality of semiconductor chips 12 flip-chip bonded to the circuit portion 11, and an underfill 13 formed between the circuit portion 11 and the semiconductor chips 12.

Referring to FIG. 1B, an encapsulant 14 is formed on the circuit portion 11 for encapsulating the semiconductor chips 12 and the underfill 13.

Referring to FIG. 1C, an upper portion of the encapsulant 14 is removed to expose the semiconductor chips 12.

Referring to FIG. 1D, the silicon wafer 10 is thinned to form a thinned silicon wafer 10′. For example, the thickness h of the silicon wafer 10 before thinning is about 700 um (shown in FIG. 1C) and the thickness h′ of the thinned silicon wafer 10′ is 50 um. In particular, the silicon wafer 10 is thinned by a mechanical grinding process.

Referring to FIG. 1E, the silicon wafer 10′ is removed by chemical etching, and a plurality of openings 15 are formed in the adhesive layer 100 to expose conductive pads 110 of the circuit portion 11. Then, an insulating layer 17 made of such as polybenzoxazole (PBO) is formed on the circuit portion 11, exposing the conductive pads 110 of circuit portion 11. Thereafter, a UBM (Under Bump Metallurgy) layer 180 is formed on the conductive pads 110 and a plurality of conductive elements 18 such as solder balls are formed on the UBM layer 180 on the conductive pads 110.

Referring to FIG. 1F, a singulation process is performed along cutting paths s of FIG. 1E to obtain a plurality of semiconductor packages 1.

However, the chemical etching process for removing the silicon wafer 10′ is very time-consuming, thus resulting in a low product yield and an increase in the fabrication cost.

Further, after the silicon wafer 10′ is removed, since the adhesive layer 100 still remains covering the conductive pads 110, the adhesive layer 100 needs to be partially removed by a chemical method so as to form the openings 15 exposing the conductive pads 110. Such a chemical method also reduces the product yield and increases the fabrication cost.

Therefore, how to overcome the above-described drawbacks has become critical.

### SUMMARY OF THE INVENTION

In view of the above-described drawbacks, the present invention provides an electronic packaging structure, which comprises: a circuit portion having opposite first and second sides; at least an electronic element disposed on the first side of the circuit portion; and a glass carrier disposed on the second side of the circuit portion.

The above-described structure can further comprise an encapsulant formed on the first side of the circuit portion for encapsulating the electronic element.

The present invention further provides a method for fabricating an electronic package, which comprises the steps of: providing an electronic structure, wherein the electronic structure comprises a glass carrier, a circuit portion formed on the glass carrier and at least an electronic element disposed on the circuit portion; forming an encapsulant on the circuit portion for encapsulating the electronic element; and removing the glass carrier.

After removing the glass carrier, the above-described method can further comprise forming a plurality of conductive elements on the circuit portion.

After removing the glass carrier, the above-described method can further comprise performing a singulation process.

In the above-described structure and method, an underfill can be formed between the circuit portion and the electronic element.

In the above-described structure and method, the glass carrier and the circuit portion can be bonded through a release film and the glass carrier can be removed through the release film.

In the above-described structure and method, the electronic element can be exposed from the encapsulant.

Therefore, by replacing a silicon wafer with a glass carrier, the present invention dispenses with an adhesive layer and allows quick removal of the glass carrier, thus saving a large amount of time, increasing the product yield and reducing the fabrication cost.

Further, since the second side of the circuit portion is exposed after the glass carrier is removed, a plurality of solder balls can be directly formed on the second side of the circuit portion or other devices can be directly connected to the second side of the circuit portion. Therefore, the present invention greatly increases the product yield and reduces the fabrication cost.

### BRIEF DESCRIPTION OF DRAWINGS

FIGS. 1A to 1F are schematic cross-sectional views showing a method for fabricating a semiconductor package according to the prior art; and

FIGS. 2A to 2F are schematic cross-sectional views showing a method for fabricating an electronic package according to the present invention.

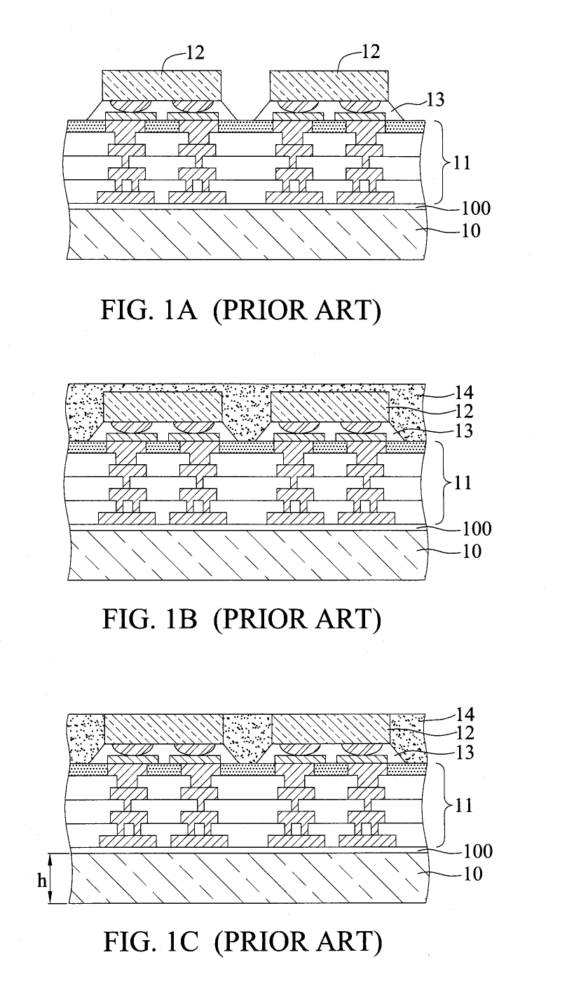

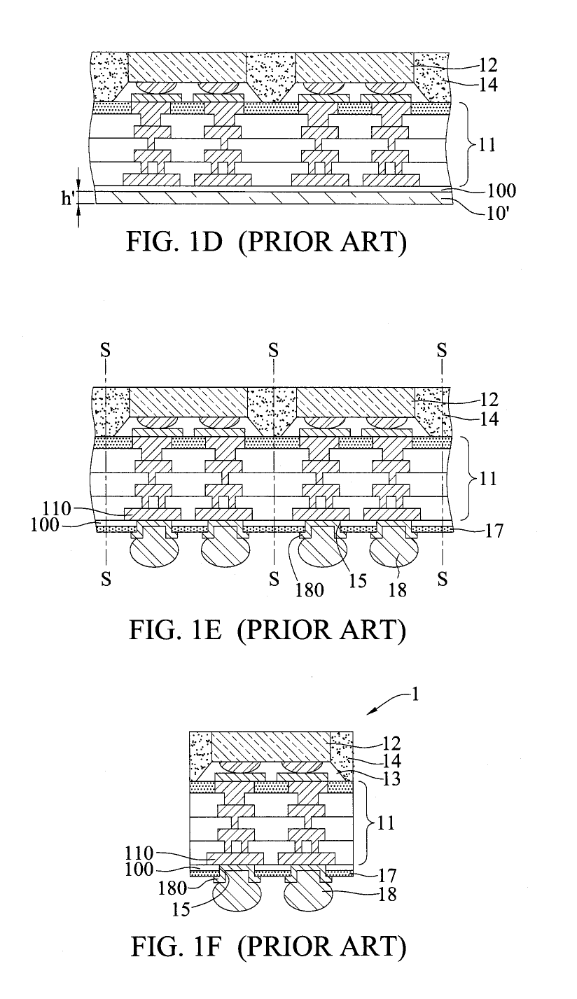

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

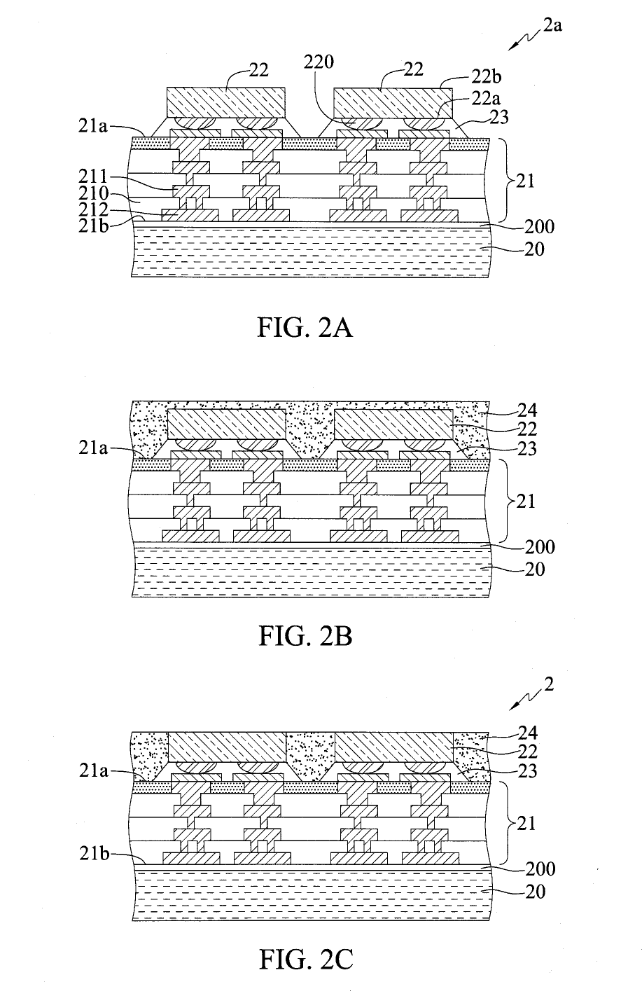

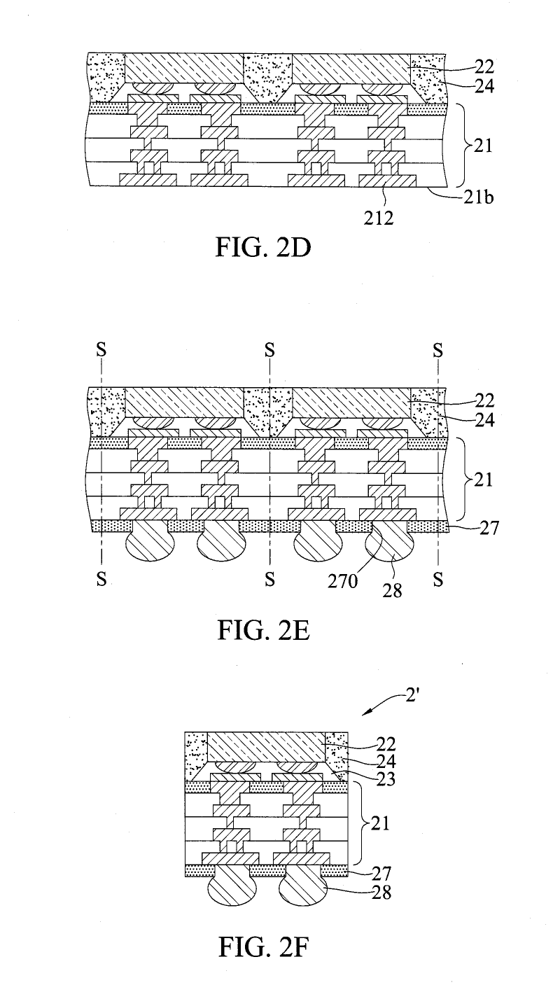

FIGS. 2A to 2F are schematic cross-sectional views showing a method for fabricating an electronic package 2′ according to the present invention.

Referring to FIG. 2A, an electronic structure 2a is provided. The electronic structure 2a has a glass carrier 20 having a release film 200, a circuit portion 21 formed on the release film 200 of the glass carrier 20, a plurality of electronic elements 22 bonded to the circuit portion 21, and an underfill 23 formed between the circuit portion 21 and the electronic elements 22.

Each of the electronic elements 22 can be an active element such as a semiconductor chip, a passive element such as a resistor, a capacitor or an inductor, or a combination thereof. In the present embodiment, each of the electronic elements 22 is an active element having an active surface 22a and an inactive surface 22b opposite to the active surface 22a.

The circuit portion 21 has a plurality of dielectric layers 210 and a plurality of circuit layers 211 stacked alternately. The circuit portion 21 has a first side 21a and a second side 21b opposite to the first side 21a. The active surfaces 22a of the electronic elements 22 are bonded to the circuit layer 211 of the first side 21a of the circuit portion 21 through a plurality of conductive bumps 220, and the conductive bumps 220 are encapsulated by the underfill 23. The second side 21b of the circuit portion 21 is bonded to the glass carrier 20. Further, the second side 21b of the circuit portion 21 has a plurality of conductive pads 212.

The circuit layers 211 are wafer-level circuits instead of packaging substrate-level circuits. Currently, the packaging substrate-level circuits have a minimum line width/pitch of 12/12 um, but the wafer-level circuits have a minimum line width/pitch of 3/3 um.

Referring to FIG. 2B, an encapsulant 24 is formed on the first side 2a of the circuit portion 21 to encapsulate the electronic elements 22 and the underfill 23.

Referring to FIG. 2C, an upper portion of the encapsulant 24 is selectively removed to expose the electronic elements 22, thereby obtaining a plurality of electronic packaging structures 2. Alternatively, in another embodiment, the electronic elements 22 of the electronic packaging structures 2 are not exposed from the encapsulant 24.

Referring to FIG. 2D, the glass carrier 20 is removed through the release film 200, thereby exposing the second side 21b of the circuit portion 21 and the conductive pads 212.

Referring to FIG. 2E, a plurality of conductive elements 28 such as solder balls are formed on the second side 21b of the circuit portion 21.

In the present embodiment, an insulating layer 27 made of such as a solder mask material or PBO is selectively formed on the second side 21b of the circuit portion 21 and has a plurality of openings 270 exposing the conductive pads 212. As such, the conductive elements 28 are formed on the conductive pads 212 in the openings 270 of the insulating layer 27.

Referring to FIG. 2F, a singulation process is performed along cutting paths S of FIG. 2E to obtain a plurality of electronic packages 2′.

In other embodiments, the singulation process can be performed before formation of the insulating layer 27 and the conductive elements 28.

In a subsequent process, the electronic package 2′ can be disposed on an electronic device such as a circuit board (not shown) through the conductive elements 28, and an underfill (not shown) can be formed between the electronic package 2′ and the electronic device to secure and protect the conductive elements 28.

Therefore, by replacing the conventional silicon wafer with the glass carrier 20 and bonding the glass carrier 20 to the second side 21b of the circuit portion 21 through the release film, the present invention dispenses with the conventional adhesive layer. Compared with the prior art, the glass carrier 20 can be quickly removed through the release film 200 so as to save a large amount of time (by dispensing with such as the conventional mechanical grinding and chemical etching processes), increase the product yield and reduce the fabrication cost.

Further, since the second side 21b of the circuit portion 21 is exposed after the glass carrier 20 is removed through the release film 200, the solder balls 28 can be directly formed on the conductive pads 212 or other devices can be directly connected to the conductive pads 212. As such, the present invention dispenses with such as the conventional process for forming openings in the adhesive layer and hence saves a large amount of time. Therefore, the present invention increases the product yield and reduces the fabrication cost.

The present invention further provides an electronic packaging structure 2, which has: a circuit portion 21 having opposite first and second sides 21a, 21b; at least an electronic element 22 disposed on the first side 21a of the circuit portion 21; and a glass carrier 20 disposed on the second side 21b of the circuit portion 21.

The glass carrier 20 can be disposed on the second carrier 21b of the circuit portion 21 through a release film 200.

In an embodiment, an underfill 23 is formed between the first side 21a of the circuit portion 21 and the electronic element 22.

In an embodiment, an encapsulant 24 is formed on the first side 21a of the circuit portion 21 for encapsulating the electronic element 22.

The electronic element 22 can be selectively exposed from the encapsulant 24.

Therefore, by disposing the glass carrier on the second side of the circuit portion through the release film, the present invention dispenses with the conventional adhesive layer and allows quick removal of the glass carrier, thus saving a large amount of time, increasing the product yield and reducing the fabrication cost.

Further, after the glass carrier is removed, the solder balls can be directly formed on the conductive pads or other devices can be directly connected to the conductive pads, thereby eliminating the need of the conventional process for forming openings in the adhesive layer. Therefore, the present invention increases the product yield and reduces the fabrication cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims

What is claimed is:

1. An electronic packaging structure, comprising:
a circuit portion having opposite first and second sides;
at least an electronic element disposed on the first side of the circuit portion; and
a glass carrier disposed on the second side of the circuit portion.

2. The structure of claim 1, wherein the glass carrier is bonded to the second side of the circuit portion through a release film.

3. The structure of claim 1, further comprising an underfill formed between the first side of the circuit portion and the electronic element.

4. The structure of claim 1, further comprising an encapsulant formed on the first side of the circuit portion for encapsulating the electronic element.

5. The structure of claim 4, wherein the electronic element is exposed from the encapsulant.

6. A method for fabricating an electronic package, comprising the steps of:
providing an electronic structure, wherein the electronic structure comprises a glass carrier, a circuit portion formed on the glass carrier and at least an electronic element disposed on the circuit portion;
forming an encapsulant on the circuit portion for encapsulating the electronic element; and
removing the glass carrier.

7. The method of claim 6, wherein the electronic structure further comprises an underfill formed between the circuit portion and the electronic element

8. The method of claim 6, wherein the glass carrier and the circuit portion are bonded through a release film.

9. The method of claim 8, further comprising removing the glass carrier through the release film.

10. The method of claim 6, further comprising removing a portion of the encapsulant to expose the electronic element.

11. The method of claim 6, after removing the glass carrier, further comprising forming a plurality of conductive elements on the circuit portion.

12. The method of claim 6, after removing the glass carrier, further comprising performing a singulation process.
